(19) United States
(12) Patent Application Publication
(10) Pub. No.: US 2004/0084766 A1
(43) Pub. Date: May 6, 2004

(54) System-in-a-package device

(76) Inventors: Pei-Ying Shieh, Hsinchu (TW); Wen-Fu Hsu, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/283,148

(22) Filed: Oct. 30, 2002

(51) Int. Cl. H01L 23/34

(52) U.S. Cl. 257/724

(57) ABSTRACT

A system-in-a-package device installs a second surface of an integrated passive devices (IPD) substrate onto a bearing substrate to achieve electric connection. At least an active device is then installed on a first surface of the IPD substrate by means of flip chip or wire bonding to achieve electric connection. Next, an encapsulant is formed to at least cover the active device or its contacts with the IPD substrate for protection. The system-in-a-package device uses conducting holes of the bearing substrate as contacts with the exterior. Thereby, more functions can be directly integrated into the same package to have the advantages of small package size, increased efficiency, and fast fabrication speed.

### FIELD OF THE INVENTION

The present invention relates to an integrated circuit (IC) packaging technique and, more particularly, to a system-in-a-package device, which directly installs several active devices onto an integrated passive devices (IPD) substrate.

### BACKGROUND OF THE INVENTION

Because of the progress of IC technology, the enhancement of levels and functions of electronic products tends to multiple functions, high speeds, large capacities, high densities, and low weights. In order to meet these requirements, in addition to continual advancement of the IC fabrication techniques, many novel packaging techniques and materials have been developed.

In order to conform to high-density package devices to develop compact electronic system products, the size of conventional single chip package has become the burden of system products. Although the newer single chip BGA (ball grid array) technique can meet the requirement of the number of pins, it cannot satisfy the requirements of size and thickness of package. Only the miniBGA or CSP (chip scale package) can meet these requirements. In order to accomplish higher functional assembly, it is necessary to integrate many chips into a module to accomplish fast signal transmission and processing. It is even necessary to integrate passive devices into the same architecture. Thereby, much more functions can be integrated into a limited space to enhance the competitiveness.

In addition to providing the functions of IC protection, space adaptation, and signal transmission, conventional electronic packages are also responsible for the quality of signal transmission and heat radiation. The faster the speed of ICs, the more important role the electronic packages play. At this time, ICs may need specially designed electronic packages to enhance various functions. Due to increase of the transmission speed of signal, some electronic packages start to integrate some passive devices like resistors and capacitors. In order to accomplish a much higher whole function, several ICs needing to cooperate close together are even integrated into the same package to enhance the speed and function.

As in the disclosure of U.S. Pat. No. 5,784,261, in a conventional module integrating several ICs, after at least an active semiconductor device is directly installed on a substrate, electric connections are formed by using a modular package and a circuit board. However, the active device is directly installed on the substrate, but is not integrated with passive devices. Therefore, the system-in-a-package benefit is not obtained. The modular package is only protected by molding compound after the assembly is finished. Additionally, because this kind of structure has no metallic shielding structure and heat-radiating structure, the function of each device thereon cannot be completely protected.

Accordingly, the present invention aims to propose a system-in-a-package device capable of integrating all circuits on ICs to effectively resolve the problems in the prior art.

### SUMMARY AND OBJECTS OF THE PRESENT INVENTION

The primary object of the present invention is to provide a system-in-a-package device, which directly installs several active devices onto an integrated passive devices (IPD) substrate without additionally installing passive devices like resistors, capacitors, or inductors, hence integrating more functions into the same package to enhance the speed and function.

Another object of the present invention is to provide a system-in-a-package device, which has both the characteristics of small package size and increased efficiency and the advantage of fast fabrication speed, and thus can be mass-produced.

Yet another object of the present invention is to provide a system-in-a-package device, which has the characteristics of a shielding structure and a heat-radiating structure.

To achieve the above objects, a system-in-a-package device of the present invention comprises a bearing substrate having a plurality of conducting holes therein. An integrated passive devices (IPD) substrate is installed on the surface of the bearing substrate. At least an active device is installed on the other surface of the IPD substrate. The active device is electrically connected with the IPD substrate. An encapsulant at least covers the active device or its contacts with the IPD substrate. The conducting holes of the bearing substrate are used as contacts with the exterior.

The various objects and advantages of the present invention will be more readily understood from the following detailed description when read in conjunction with the appended drawings, in which:

### BRIEF DESCRIPTION OF DRAWING

FIG. 1 is a diagram of a system-in-a-package device according to a first embodiment of the present invention;

FIG. 2 is a diagram of a system-in-a-package device according to a second embodiment of the present invention;

FIG. 3 is a diagram of a system-in-a-package device according to a third embodiment of the present invention;

FIG. 4 is a diagram of a system-in-a-package device according to a fourth embodiment of the present invention; and

FIG. 5 is a diagram of a system-in-a-package device according to a fifth embodiment of the present invention.

### DETAILED DESCRIPTION OF PREFERRED EMBODIMENT

The present invention directly integrates integrated passive devices (IPD) like resistors, capacitors, or inductors into a substrate, and then installs at least an active device on the surface of the IPD substrate, thereby accomplishing a system package integrating all circuits on ICs and thus effectively resolving the drawbacks in the prior art.

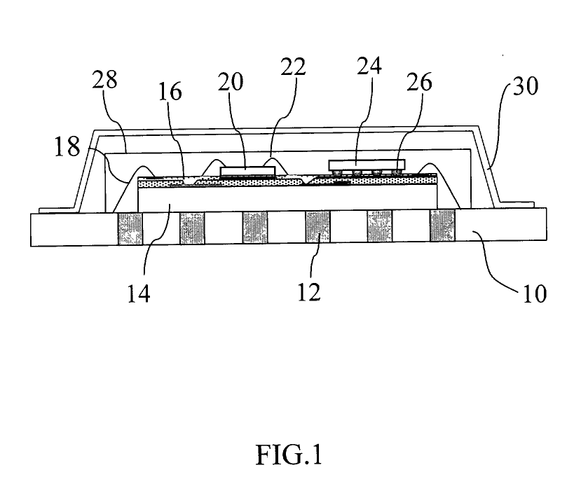

As shown in FIG. 1, a system-in-package device comprises a bearing substrate 10, which has several through conducting holes 12 thereon. An IPD substrate 14 with a plurality of passive devices 16 formed thereon is also provided. The IPD substrate 14 has a first surface and a second surface. The second surface of the IPD substrate 14 is installed on the surface of the bearing substrate 10. A plurality of wires 18 are used to achieve electric connection between the IPD substrate 14 and the bearing substrate 10 by means of wire bonding. Two active devices (a first active device 20 and a second active device 24) like semiconductor chips, micro electromechanical system (MEMS) devices, or radio-frequency (RF) devices are installed on the first surface of the IPD substrate 14. The first active device 20 is installed on the first surface of the IPD substrate 14 to achieve electric connection therewith through wire bonding of a plurality of leads 22. The second active device 24 is installed on the first surface of the IPD substrate 14 to achieve electric connection therewith through a plurality of bumps 26 by means of flip chip.

A encapsulant 28 is formed on the surface of the bearing substrate 10 by means of vacuum printing to cover the IPD substrate 14, the wires 18, the first active device 20, and the second active device 24. The encapsulant 28 can provide mechanical protection. Additionally, a shielding metallic lid 30 can be disposed on the surface of the bearing substrate 10 to prevent interference of external electromagnetic waves in addition to avoiding damage of the active devices 20 and 24 due to external forces (e.g., impact, dusts, or moisture). The system-in-a-package device uses the conducting holes of the bearing substrate as contacts with the exterior so that the bearing substrate can be installed onto other electronic devices to achieve electric connection.

The above bearing substrate 10 is a ceramic substrate, a multi-layered substrate or a printed circuit board (such as FR-4 or BT substrate), or a flexible substrate. The material of the IPD substrate 14 is selected among the group of silicon, glass, high-resistance silicon, and ceramic, and can also be a MEMS substrate or a micro optical electromechanical system (MOEMS) substrate.

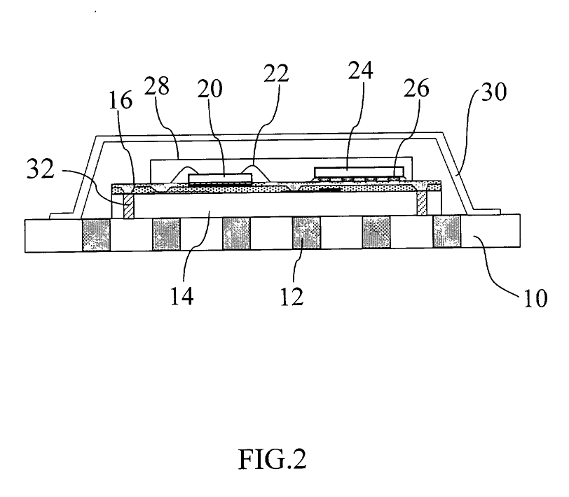

As shown in FIG. 2, a plurality of conducting hole 32 are disposed in the IPD substrate 14. The conducting holes 32 are used to achieve electric connection between the IPD substrate 14 and the bearing substrate 10. The encapsulant 28 only covers the first active device 20 and the second active device 24 or contacts of the active device with IPD substrate 14. Other structures are the same as those in FIG. 1 and thus will not be further described.

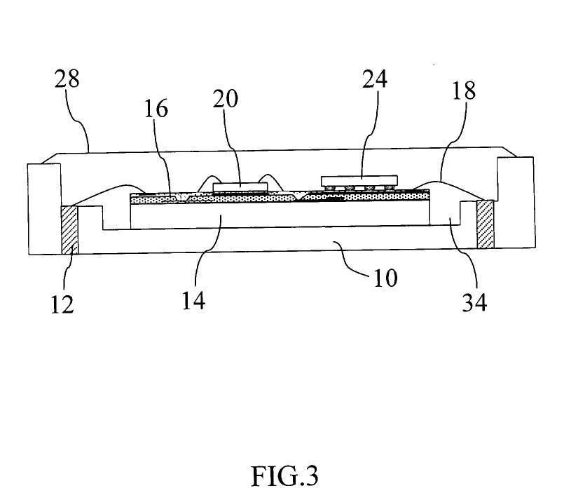

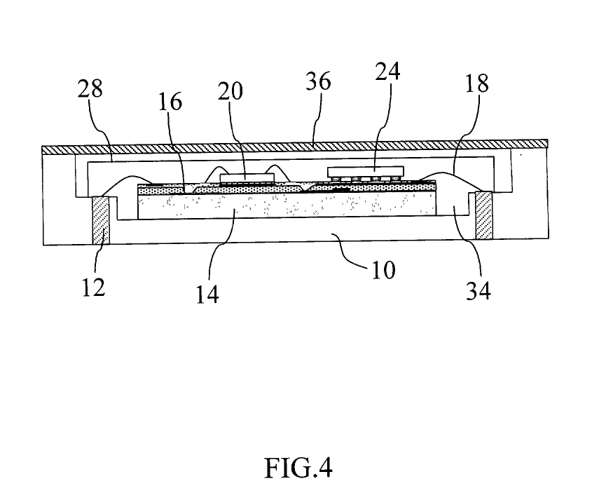

As shown in FIG. 3, a recess 34 is disposed at the center of the surface of the bearing substrate 10. The IPD substrate 14 and each device thereon are received in the recess 34. A plurality of wires 18 are used to achieve electric connection between the IPD substrate 14 and the bearing substrate 10 by means of wire bonding. The encapsulant 28 is located in the recess 34 and covers all the devices. The encapsulant 28 further fills up the recess 34. Besides, as shown in FIG. 4, if the encapsulant 28 only covers the wires 18, the IPD substrate 14 and each device thereon, and does not fill up the recess 34, a lid 36 can cover above the bearing substrate 10 to seal the recess 34. Other structures are the same as those of the system-in-a-package device shown in FIG. 3 and thus will not be further described.

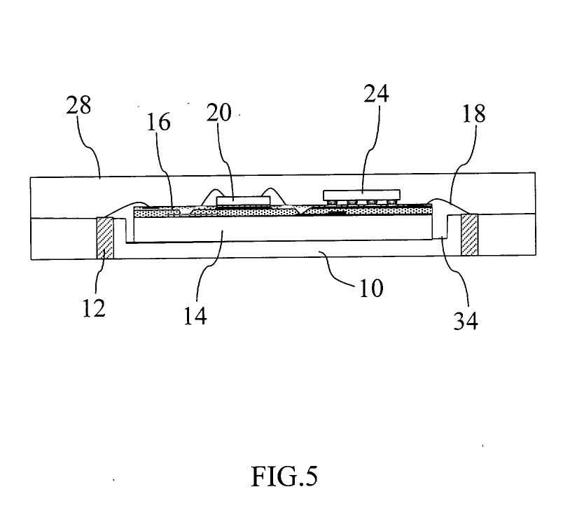

Additionally, as shown in FIG. 5, when the depth of the recess 34 is smaller than the thickness of the IPD substrate 14, after the IPD substrate 14 is installed in the recess 34, the IPD substrate will be exposed out of the recess. A plurality of wires 18 are then used to achieve electric connection between the IPD substrate 14 and the bearing substrate 10 by means of wire bonding. In addition to filling up the recess 34, the encapsulant 28 also completely covers all the devices.

To sum up, the present invention directly installs several active devices onto an IPD substrate without additionally installing passive devices like resistors, capacitors, or inductors, hence directly integrating more functions into the same package to enhance the speed and function. Moreover, because the present invention integrates all the devices into the same package, its has both the characteristics of small package size and increased efficiency and the advantage of fast fabricating speed, and thus can be mass produced.

Although the present invention has been described with reference to the preferred embodiments thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A system-in-a-package device comprising:
a bearing substrate having several through conducting holes disposed thereon;
an integrated passive devices substrate having a first surface and a second surface, said second surface of said integrated passive devices substrate being installed onto said bearing substrate to achieve electric connection;
at least an active device installed on said first surface of said integrated passive devices substrate and achieving electric connection with said integrated passive devices substrate; and
an encapsulant covering said active device or contacts of said active device with said integrated passive devices substrate.

2. The system-in-a-package device as claimed in claim 1, wherein said bearing substrate is a ceramic substrate, a multi-layered substrate, a printed circuit board, a flexible substrate.

3. The system-in-a-package device as claimed in claim 1, wherein said integrated passive devices substrate achieves electric connection with said bearing substrate by using wires or said conducting holes.

4. The system-in-a-package device as claimed in claim 1, wherein a recess is formed in said bearing substrate so that said integrated passive devices substrate and each device thereon can be received therein, and said encapsulant is used to cover all said devices.

5. The system-in-a-package device as claimed in claim 4, wherein a lid covers above said bearing substrate to seal said recess.

6. The system-in-a-package device as claimed in claim 1, wherein the material of said integrated passive devices substrate is selected among the group of silicon, glass, high-resistance silicon, and ceramic.

7. The system-in-a-package device as claimed in claim 1, wherein a shielding metallic lid is further installed on a surface of said bearing substrate.

8. The system-in-a-package device as claimed in claim 1, wherein said active device is installed onto said first surface of said integrated passive devices substrate by means of flip chip or wire bonding.

9. The system-in-a-package device as claimed in claim 1, wherein said active device is a semiconductor chip, a micro electromechanical system device, or a radio-frequency device.

10. The system-in-a-package device as claimed in claim 1, wherein said encapsulant is formed on said first surface of said integrated passive devices substrate by means of vacuum halftone printing or dispensing to cover said active device or contacts of said active device with said integrated passive devices substrate.
